(19) United States
(12) Patent Application Publication
(10) Pub. No.: US 2025/0132207 A1
(43) Pub. Date: Apr. 24, 2025

(54) OPTIMIZATION FOR LOCAL CHEMICAL EXPOSURE

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/686,832

(22) PCT Filed: Aug. 25, 2022
(86) PCT No.: PCT/US2022/041514

§ 371 Date: Feb. 26, 2024

Related U.S. Application Data
(60) Provisional application No. 63/236,847, filed on Aug. 25, 2021.

(51) Int. Cl. H01L 21/66; H01L 21/027

(52) U.S. Cl. CPC H01L 22/20; H01L 21/0271

(57) ABSTRACT

A method of microfabrication includes depositing a first layer of a first resist that includes a first chemical marker on a substrate, measuring a first fluorescence intensity of the first layer from the first fluorescent chemical marker, forming a first relief pattern from the first layer of the first resist, and measuring a second fluorescence intensity of the first layer from the first chemical marker subsequent to forming the first relief pattern. Then, the method includes depositing a solubility-shifting agent on the first relief pattern, depositing a second resist on the first relief pattern, diffusing the solubility-shifting agent into the second resist to provide a solubility-shifted region of the second resist, developing the second resist such that the solubility-shifted region of the second resist is dissolved and a portion of the substrate is exposed, and measuring a third fluorescence intensity of the first layer from the first chemical marker.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a photoresist, to a pattern of actinic radiation and subsequently developing the photoresist to form a relief pattern. The relief pattern then acts as an etch mask, which, when one or more etching processes are applied to the substrate, covers portions of the substrate that are not to be etched. Processing may then continue with additional steps of material deposition, etching, annealing, photolithography, and so forth, with various steps repeated until fabricating a transistor or integrated circuit.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of microfabrication including depositing a first layer of a first resist on a substrate, wherein the first resist includes a first fluorescent chemical marker, measuring a first fluorescence intensity of the first layer from the first fluorescent chemical marker, after measuring a first fluorescence intensity of the first layer, forming a first relief pattern from the first layer of the first resist, and measuring a second fluorescence intensity of the first layer from the first chemical marker subsequent to forming the first relief pattern. Then, the method includes depositing a solubility-shifting agent on the first relief pattern, depositing a second resist on the first relief pattern, diffusing the solubility-shifting agent a predetermined distance into the second resist to provide a solubility-shifted region of the second resist, wherein the solubility-shifting region of the second resist borders the first relief pattern, developing the second resist such that the solubility-shifted region of the second resist is dissolved, providing openings between the first relief pattern and the second resist where a portion of the substrate is exposed, and measuring a third fluorescence intensity of the first layer from the first chemical marker subsequent to forming the first relief pattern from the first layer.

In another aspect, embodiments disclosed herein relate to a method of microfabrication including depositing a first layer of a first resist on a substrate, wherein the first resist includes a first fluorescent chemical marker, measuring a first fluorescence intensity of the first layer from the first fluorescent chemical marker, after measuring a first fluorescence intensity of the first layer, forming a first relief pattern from the first layer of the first resist, and measuring a second fluorescence intensity of the first layer from the first chemical marker subsequent to forming the first relief pattern. Then, the method includes depositing a solubility-shifting agent on the first relief pattern, diffusing the solubility-shifting agent a predetermined distance into the first resist to provide a solubility-shifted region of the first resist, depositing a second resist on the first relief pattern, developing the first resist such that the solubility-shifted region of the first resist is dissolved, providing openings between the first relief pattern and the second resist where a portion of the substrate is exposed, and measuring a third fluorescence intensity of the first layer from the first chemical marker subsequent to developing the first resist.

Other aspects and advantages of the claimed subject matter will be apparent from the following description and the appended claims.

### BRIEF DESCRIPTION OF DRAWINGS

FIG. 1 is a block-flow diagram of a method in accordance with one or more embodiments of the present disclosure.

FIGS. 2A-F are schematic illustrations of coated substrates at respective points of a method in accordance with one or more embodiments of the present disclosure.

### DETAILED DESCRIPTION

In the field of lithography, surface driven chemical exposure is a novel way to create small features, as well as optimize substrate patterning performance and capability. Surface driven chemical exposure and diffusion of various chemicals to impart solubility shifts can access dimensions in the single nanometer range, which is significantly below the resolution of conventional 193 nm lithography. Similar to optical lithography, there are various process control steps to control final dimensional capabilities. Such processes ideally control initial layer formation, concentration control, dimensional feedback, and final process feedback capabilities, which can make use of the flexible capabilities to control final dimension beyond just a treated CD (critical dimension).

Accordingly, the present disclosure generally relates to methods and systems for process control. Such methods and systems may include new target designs, new feedback mechanisms, new control points embedded within integration flows to optimize new integration plans, and new target and chemistry designed to simplify measurements, and in particular, to optimize for techniques like fluorescence or imaging. Systems and methods described herein may be used with conventional semiconductor fabrication tools and equipment.

The methods and systems described herein may be used for different control and monitor requirements. In one or more embodiments, process controls are enabled for chemical spacers including simple spacers and cross spacers, such as spacers that are crossed on different planes. In some embodiments, process controls are enabled for selectivity and dual patterning, including, for example, single patterning, dual selector, and line contact/stitching.

In one or more embodiments, methods include measuring a projected area, volume, or shape of each feature and then using such measurements to control a thickness, thermal activation, or optical activation, and environment (which can control top overhang) as appropriate in a feedback system. Controlling these dimensions may provide control of the final shape of the resulting features.

Methods and systems of one or more embodiments, in relying on both chemical processes and diffusional properties, provide the unique ability to add control features to the input chemistry itself, and the process of measuring such chemistry.

For example, an anti-spacer process flow is a track-based process that creates narrow trenches by acid diffusion from structures of a first relief pattern into a second material that fills openings defined by the first relief pattern. Acid diffusion is precisely controlled by exposure dose, time, temperature, and material composition. Accordingly, sub-resolution trenches can be created, down to single digit nanometer dimensions.

As with conventional microfabrication processes, in the present methods of microfabrication metrology is useful to identify any processing step that needs to be corrected. For example, in an anti-spacer method, as briefly described above, there are different measurement options as well as different controls. Similar to the control scheme of conventional double patterning, in the present method post resist diameter can be measured using any metrology technique conventionally used in the art, such as scatterometry, electron microscopy, and scanning probe microscopy (SPM).

In present methods of microfabrication, feedback for the anti-spacer (e.g., the gaps between features of one or more relief patterns) formation can be involved because, in receiving such feedback, the development/activation can be altered, or the diffused quantity/composition can be altered depending on materials, equipment, and other random effects. Accordingly, it is beneficial to have control methods to validate that the features being formed have the desired size and shape. For typical spacer formation, metrology is different. Sidewall spacers are typically formed by vapor-based conformal deposition on inorganic material, then a directional etch (spacer open etch) to clear material from tops of mandrels and floor material. Metrology is then performed to measure CDs of sidewall spacers created. But with anti-spacers created primarily within a track tool, or a coater-developer, a different metrology solution is needed. Methods disclosed herein provide that ability to monitor process flow of a track-based process at any point during such process.

As described above, an anti-spacer technique is a track-based process. A typical microfabrication process using an anti-spacer technique initially includes forming a first relief pattern on a substrate. The first relief pattern may include a first resist. The first relief pattern may be formed by first layering the first resist on the substrate, then exposing the first resist to a pattern of actinic radiation, and finally developing the first resist such that specific features remain on the substrate. Such features make up the first relief pattern.

Then, a solubility-shifting agent such as an acid may be coated over the first relief pattern. The solubility-shifting agent may be absorbed into the first relief pattern. After which, a second resist may be deposited on the first relief pattern. The second resist may fill any gaps in the first relief pattern. The solubility-shifting agent that is absorbed into the first relief pattern may then be diffused into the second resist, such that a portion of the second resist that is exposed to the solubility-shifting agent has a different solubility than a portion of the second resist that is not exposed to the solubility-shifting agent. The exposed portion of the second resist may be soluble in a specific developer, that is then used to develop the second resist. As such, the exposed portion of the second resist may be dissolved and a portion of the substrate may be exposed. Finally, the exposed portion of the substrate may be etched.

Alternatively, when the solubility-shifting agent is absorbed into the first resist, it may induce a solubility shift in the region of the first resist that it is absorbed into. Such solubility shift may provide a solubility-shifted region of the first resist that is soluble in a specific developer. Thus, layering of the second resist and development with the specific developer may result in dissolution of the solubility-shifted region of the first resist and exposure of the substrate.

Desirable output variables of the anti-spacer method include the width of the first resist features, the width of the anti-spacers and the width of the undeveloped portion of the second resist. Secondarily, the 2D/3D shape is also material to the final etched dimensions.

In methods of one or more embodiments, in order to exhibit control over the materials, the individual layers include metrology-dedicated chemical features in their compositions. In one or more embodiments, methods include adding a metrology-dedicated chemical to one or more materials such as a first resist, a second resist, among others. For example, a resist on a substrate can have a specific chemical marker (activated or not). An example chemical marker may be a fluorescent chemical marker such as a particular dye. By measuring the changes in the fluorescence spectrum of the dye, the total volume of the resist can be measured.

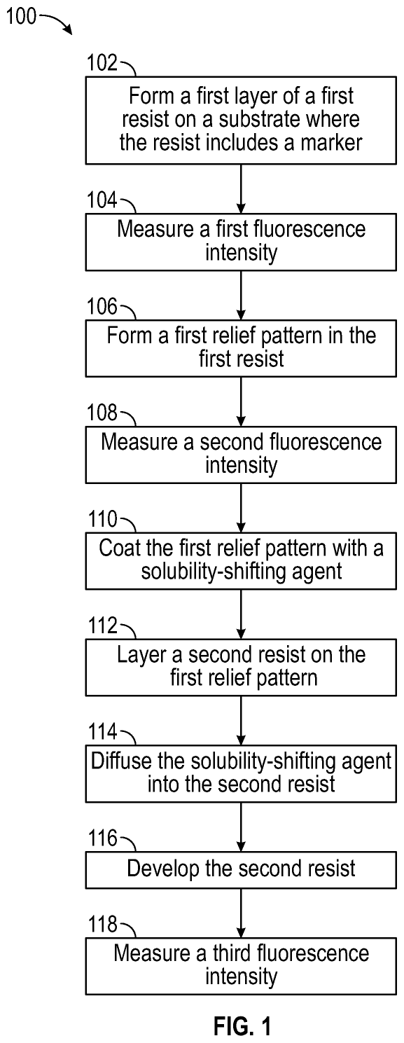

A method of process control in accordance with embodiments of the present disclosure is shown in, and discussed with reference to, FIG. 1. Initially, method 100 includes, at block 102, providing a first layer of a first resist on a substrate. Herein, the terms “semiconductor substrate” and “substrate” are used interchangeably, and may be any semiconductor material including, but not limited to, semiconductor wafers, semiconductor material layers, and combinations thereof. The first resist may include a first fluorescent chemical marker. At block 104, a fluorescence intensity of the first resist, from the first fluorescent chemical marker, is measured. Then, at block 106, the first layer of the first resist is photolithographically developed to form a first relief pattern, and a second fluorescence intensity is measured at block 108.

At block 110, the first relief pattern is coated with a solubility-shifting agent. The solubility shifting agent can be a solubilizing or hardening agent, based on the polarity of the first resist. Then, at block 112, a second resist is layered on the first relief pattern, such that any exposed portion of the substrate and the first resist are completely covered with the second resist. At block 114, the solubility-shifting agent is then diffused into the second resist, and at block 116 the second resist is developed. Diffusion of the solubility shifting agent may form a solubility-shifted region in the second resist, that may be selectively developed, forming trenches where the substrate is exposed. After developing the second resist, at block 118, the fluorescence intensity of the first fluorescent chemical marker is measured, and a critical dimension of the first resist is determined.

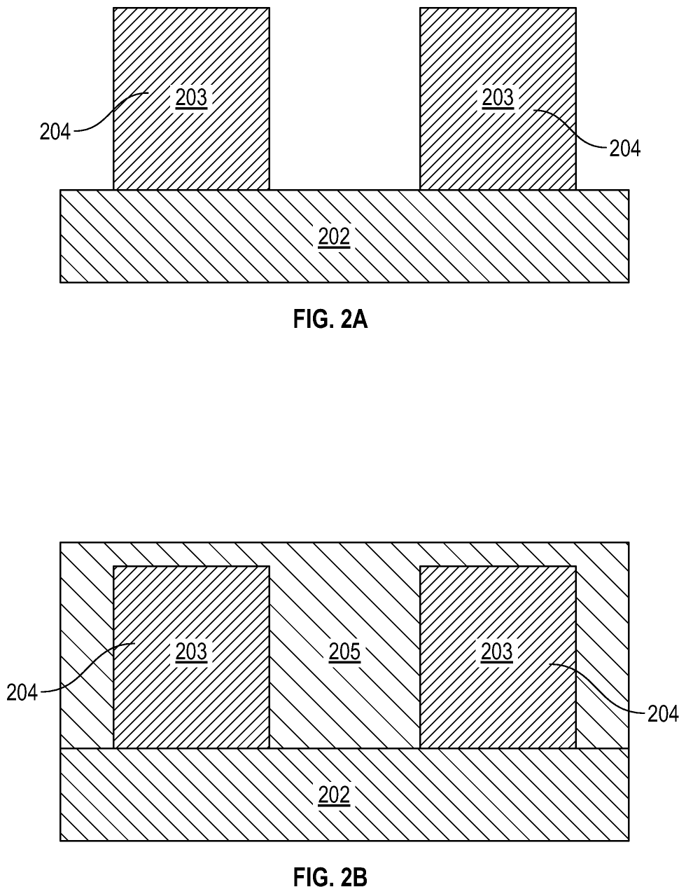

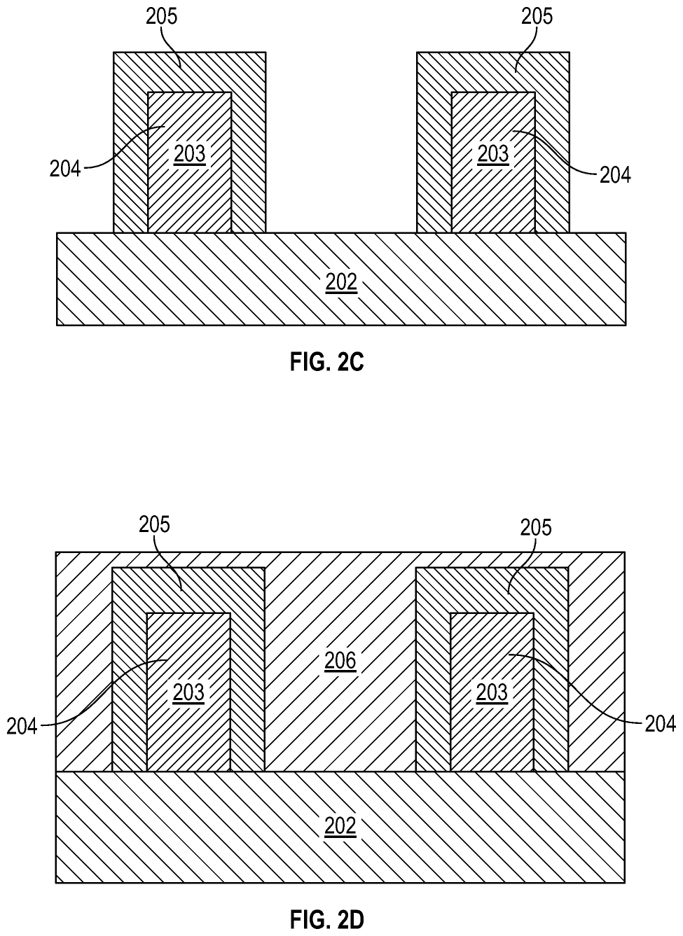

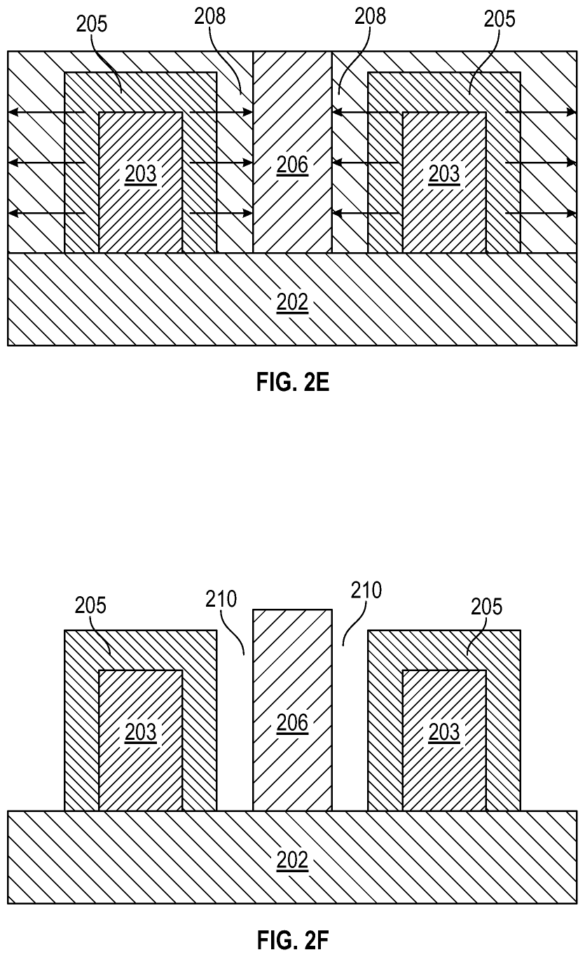

Schematic depictions of a coated substrate at various points during the method described above are shown in FIGS. 2A, 2B, 2C, 2D, 2E, and 2F. Herein “a coated substrate” refers to a substrate that is coated with one or more layers, such as a first resist layer and a second resist layer. FIG. 2A shows a substrate that has been photolithographically developed to provide a first relief pattern. FIG. 2B shows a substrate including a first relief pattern coated with a solubility-shifting agent. In FIG. 2C, a first relief pattern is shown with the absorbed solubility-shifting agent. FIG. 2D shows a second resist is layered over the substrate and the first relief pattern. FIG. 2E shows a coated substrate after the solubility-shifting agent has been diffused into the second resist. Finally, FIG. 2F shows a coated substrate after the second resist has been developed, such that an anti-spacer pattern is formed. The method of FIG. 1 and coated substrates shown in FIGS. 2A-F are discussed in detail below.

At block 102 of method 100, a first layer of a first resist is provided. FIG. 2A shows an example of a first layer 204 on a substrate 202. The first layer may be made of a first resist 203. The first resist may be a photoresist. Generally, a photoresist is a chemically amplified photosensitive composition that comprises a polymer, a photoacid generator, and a solvent. In one or more embodiments, the first resist includes a polymer. The polymer may be any standard polymer typically used in resist material and may particularly be a polymer having acid-labile groups. For example, the polymer may be a polymer made from monomers including styrene, p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the first resist. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹)₃ or an acetal group of the formula —C(O)OC(R²)₂OR³, wherein: R¹ is cach independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, cach of which is substituted or unsubstituted, cach R¹ optionally including as part of its structure one or more groups chosen from —O—, —C(O)—, —C(O)—O—, or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, cach R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The polymer can further include as polymerized a monomer comprising an acid-labile group, the decomposition of which group forms an alcohol group or a fluoroalcohol group on the polymer. Suitable such groups include, for example, an acetal group of the formula —COC(R²)₂OR³—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

In embodiments in which the first resist is a photoresist, the first resist includes a photoacid generator. The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifhioromethanesulfonate, (p-tert-butoxyphenyl)diphenylsulfonium tris (p-tert-butoxyphenyl)sulfonium trifhioromethanesulfonate, trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The resist composition may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above.

In one or more embodiments, the first resist includes a first fluorescent chemical marker. The fluorescent chemical marker may be any suitable fluorescent chemical that may be included in a resist composition. Suitable fluorescent chemicals may emit fluorescence at a wavelength ranging from about 200 nm to about 5000 nm. For example, suitable fluorescent chemicals may have a fluorescence wavelength ranging from a lower limit of one of about 200 nm, about 220 nm, about 250 nm, about 280 nm, about 300 nm, about 350 nm, and about 400 nm to an upper limit of one of about 500 nm, about 1000 nm, about 2000 nm, about 3000 nm, about 4000 nm, and about 5000 nm, where any lower limit may be paired with any mathematically compatible upper limit.

In one or more embodiments, the fluorescent chemical marker may be included in the first resist in an amount ranging from about 10⁻⁷ mol/liter to about 10⁻² mol/liter. Preferably, the fluorescent chemical marker is added at a concentration of about 10⁻⁷ mol/liter up to about 10⁻⁶ mol/liter. Thus, a comparatively small amount of fluorescent chemical marker is sufficient for measurement, and the fluorescent chemical marker will not affect the functional performance of the first resist.

The fluorescent chemical marker of one or more embodiments may be a fluorescent dye. Suitable fluorescent dyes include pyrenes, BODIPY dyes, cyanine 3dyes, cyanine 5 dyes, cyanine 5.5 dyes, cyanine 7 dyes, fluorescein dyes, rhodamine dye, Coumarin dyes, 800CW dye, BP Fluor 680, BP Fluor 647, BP Fluor 594, BP Fluor 568, BP Fluor 546, BP Fluor 555, BP Fluor 350, BP Fluor 488, BP Fluor 430, BP Fluor 532, 4-(9H-carbazol-9-yl)benzoate, and 4-(dicyanomethylene)-2-methyl-6-(4-dimethylaminostyryl)4H-pyran. In other embodiments, the fluorescent chemical marker, such as those listed above, may be included as a functional group on the polymer of the first resist.

At block 104 of method 100, an initial fluorescence intensity of the first layer of the first resist is measured. The fluorescence may be measured according to methods known in the art such as optical emission spectrometry or laser-induced fluorescence spectrometry, among others.

In some embodiments, the average fluorescence intensity is measured. An average fluorescence may be measured by taking fluorescence measurements across a large region, such as the full substrate area. In other embodiments, the fluorescence intensity of a small target area is measured. Small target areas may have a size ranging from about 5 μm×about 5 μm to about 50 μm×about 50 μm.

Then, at block 106, the first resist is developed to provide a first relief pattern. A shown in FIG. 2A, the first relief pattern may include features separated by gaps. Portions of the substrate may be exposed by the presence of the gaps of the first relief pattern. The features of the first relief pattern may be made of the first resist 203, and as such may include the first fluorescent chemical marker.

The first relief pattern may be formed by layering the first resist onto a substrate and the developing the first resist. The first resist may be developed according to procedures known in the art, e.g., exposure to actinic radiation followed by rinsing with a first resist developer. In order to impart a shape, or relief pattern, in the developed resist, a mask may be used to block a portion of the resist from the actinic radiation. After the actinic radiation is applied, the unexposed portion of the resist may have a different solubility than the exposed portion of the resist. Subsequent rinsing with the first resist developer will dissolve either the unexposed portion or the exposed portion. A relief pattern provided when the unexposed portion of the resist remains after rinsing with a developer is a positive tone developed resist. In contrast, a relief pattern provided when the exposed portion of the resist remains after rinsing with a developer is a negative tone developed resist.

In some embodiments, the first resist is a positive tone developed (PTD) resist. In such embodiments, the first relief pattern may include a polymer made from the above described monomers, wherein any monomers including a reactive functional group are protected. As such, a PTD first resist may be organic soluble, and thus the relief pattern may be provided by rinsing with a first resist developer that is basic. Suitable basic first resist developers include quaternary ammonium hydroxides, such as tetramethylammonium hydroxide (TMAH).

In other embodiments, the first resist is a negative resist. In such embodiments, the first relief pattern may include a polymer made from the above described monomers, wherein any monomers including a reactive functional group are not protected. Exposure to actinic radiation results in crosslinking of the polymer in areas of exposure, rendering the polymer insoluble to developers. The unexposed and thus uncrosslinked areas can then be removed using an appropriate developer to form the relief pattern.

In other embodiments, the first resist is a negative tone developed (NTD) resist. Similar to PTD resists, NTD resists may include a polymer made from the above described monomers, wherein any monomers including a reactive functional group are protected. As such, a NTD first resist may be organic soluble, but instead of developing the exposed areas with a first resist developer that is basic, the first relief pattern may be provided by rinsing the first resist with a first resist developer including an organic solvent. Suitable organic solvents that may be used as a first resist developer include n-butyl acetate (NBA) and 2-heptanone. The tone of the resist (i.e., PTD vs. negative vs. NTD) may influence the subsequent chemistry applied to the first relief pattern.

In one or more embodiments, the first resist optionally contains other additives, wherein other additives include at least one of a resin having at least either a fluorine atom or a silicon atom, a basic compound, a surfactant, an onium carboxylate, a plasticizer, a photosensitizer, a light absorbent, an alkali-soluble resin, a dissolution inhibitor, and a compound for accelerating dissolution in a developer.

As previously described, the first relief pattern may include features separated by gaps. In one or more embodiments, the features of the first relief pattern may have a thickness of about 300 Å to about 3000 Å. The gaps separating the features may leave portions of the substrate exposed.

In some embodiments, the first relief pattern is stabilized prior to coating with the solubility-shifting agent. Various resist stabilization techniques, also known as freeze processes, have been proposed such as ion implantation, UV curing, thermal hardening, thermal curing, and chemical curing. Techniques are described, for example, in US2008/0063985A1, US 2008/0199814A1 and US 2010/0330503A1.

At block 108 of method 100, a second fluorescence of the first resist may be measured. The fluorescence may be measured according to methods known in the art as described above.

At block 110 of method 100, the first relief pattern is coated with a solubility-shifting agent. A coated substrate in accordance with block 108 is shown in FIG. 2B. The solubility-shifting agent 205 is shown a coating over the first relief pattern 204 and the substrate. The thickness of the solubility-shifting agent coating is not particularly limited and may be altered based on the desired anti-spacer width. The solubility-shifting agent may be a material that is absorbed into the first resist via a bake, and in some instances herein may be referred to as an “absorbed material.” The process of absorbing, the solubility-shifting agent into the first resist is described in detailed below.

The composition of the solubility-shifting agent may depend on the tone of the first resist. Generally, the solubility-shifting agent may be any chemical that activates with light or heat. For example, when the first resist is a PTD resist, the solubility-shifting agent may include an acid or thermal acid generator (TAG). The acid or generated acid in the case of a TAG should be sufficient with heat to cause cleavage of the bonds of acid-decomposable groups of the polymer in a surface region of the first resist pattern to cause increased solubility of the first resist polymer in a specific developer to be applied. The acid or TAG is typically present in the composition in an amount of from about 0.01 to 20 wt % based on the total solids of the trimming composition.

Preferable acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Exemplary aromatic acids that are free of fluorine include wherein aromatic acids of the general formula (I):

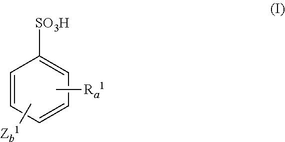

wherein: R1 independently represents a substituted or unsubstituted C1-C20alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z1 independently represents a group chosen from carboxyl, hydroxy, nitro, cyano, C1 to C5 alkoxy, formyl and sulfonic acid; a and b are independently an integer from 0 to 5; and a+b is 5 or less.

Exemplary aromatic acids may be of the general formula (II):

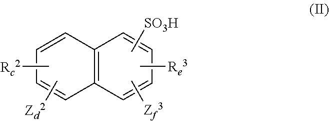

wherein: R2 and R3 each independently represents a substituted or unsubstituted C1-C20 alkyl group, a substituted or unsubstituted C5-C16 aryl group or a combination thereof, optionally containing one or more group chosen from carbonyl, carbonyloxy, sulfonamido, ether, thioether, a substituted or unsubstituted alkylene group, or a combination thereof; Z2 and Z3 each independently represents a group chosen from carboxyl, hydroxy, nitro, cyano, C1 to C5 alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility-shifting agent include those the general formula (III) or (IV):

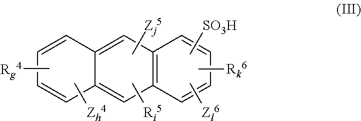

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 2; i+j is 2 or less; k and l are independently an integer from 0 to 3; and k+l is 3 or less;

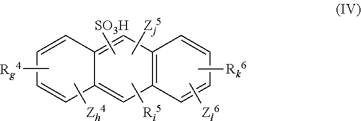

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 1; i+j is 1 or less; k and l are independently an integer from 0 to 4; and k+1 is 4 or less.

Suitable aromatic acids may alternatively be of the general formula (V):

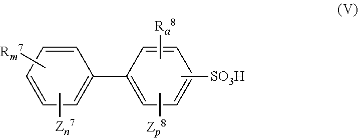

wherein: R7 and R8 each independently represents a substituted or unsubstituted C1-C20 alkyl group, a substituted or unsubstituted C5-C14 aryl group or a combination thereof, optionally containing one or more group chosen from carboxyl, carbonyl, carbonyloxy, sulfonamido, ether, thioether, a substituted or unsubstituted alkylene group, or a combination thereof; Z7 and Z8 each independently represents a group chosen from hydroxy, nitro, cyano, C1 to C5 alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may have the general formula (VI):

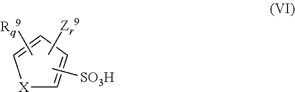

wherein: X is O or S; R9 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z9 independently represents a group chosen from carboxyl, hydroxy, nitro, cyano, C1 to C5 alkoxy, formyl and sulfonic acid; q and r are independently an integer from 0 to 3; and q+r is 3 or less.

In one or more embodiments, the acid is a free acid having fluorine substitution. Suitable free acids having fluorine substitution may be aromatic or nonaromatic. For example, free acid having fluorine substitution that may be used as solubility-shifting agent include, but are not limited to the following:

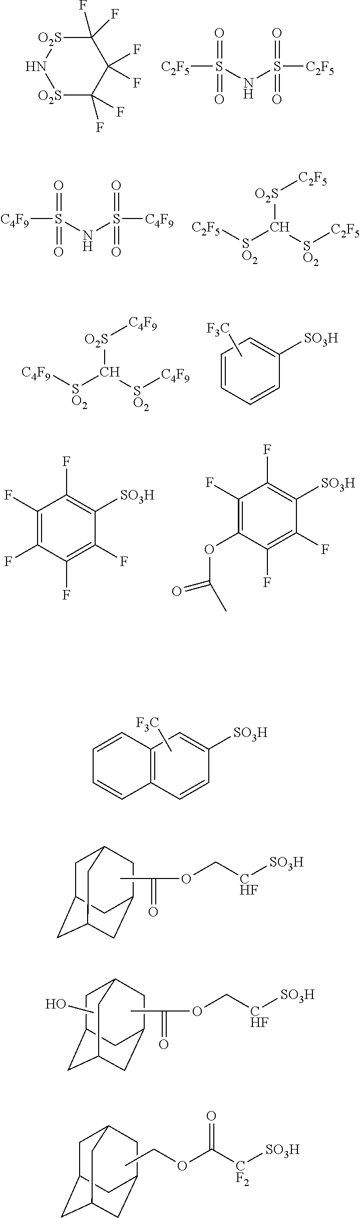

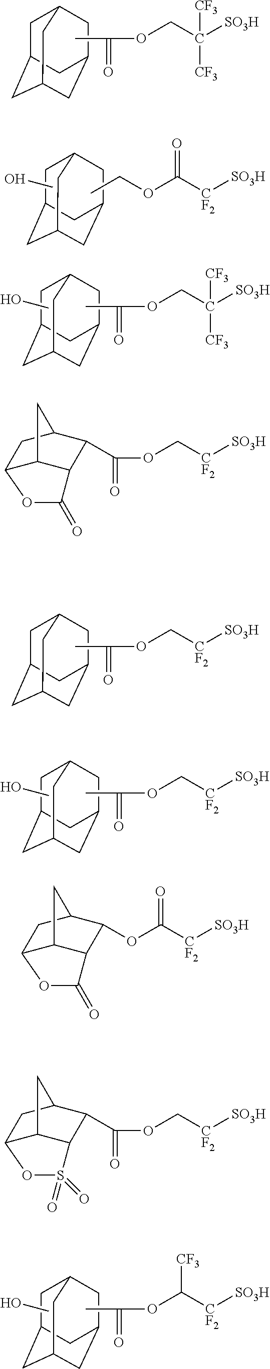

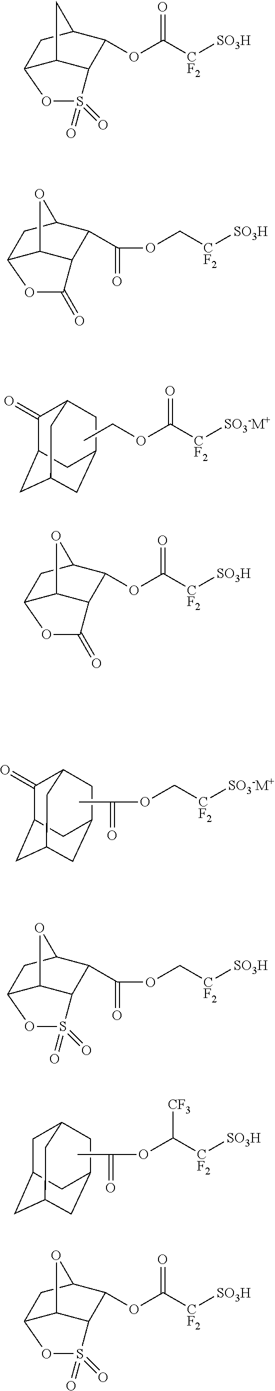

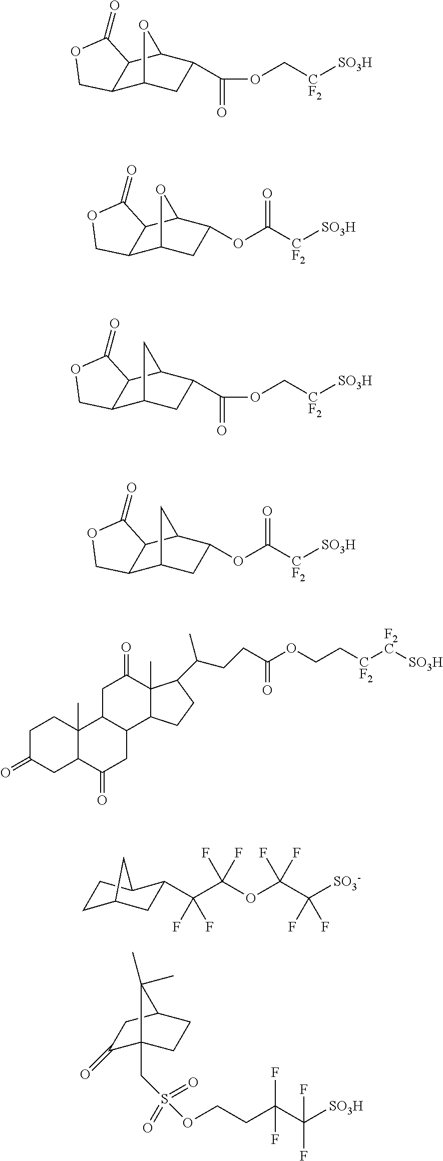

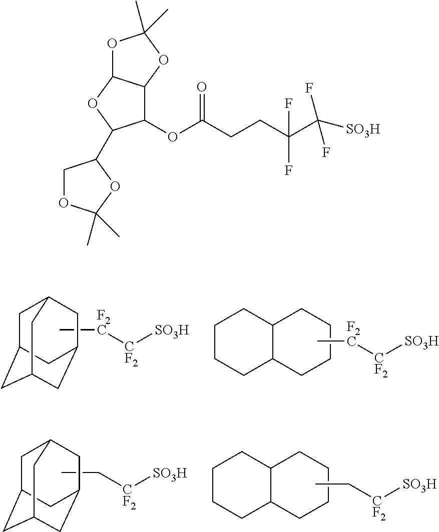

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

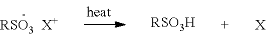

wherein RSO₃⁻ is the TAG anion and X⁺ is the TAG cation, preferably an organic cation. The cation can be a nitrogen-containing cation of the general formula (I):

(BH)⁺ (I)
which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)⁺ include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

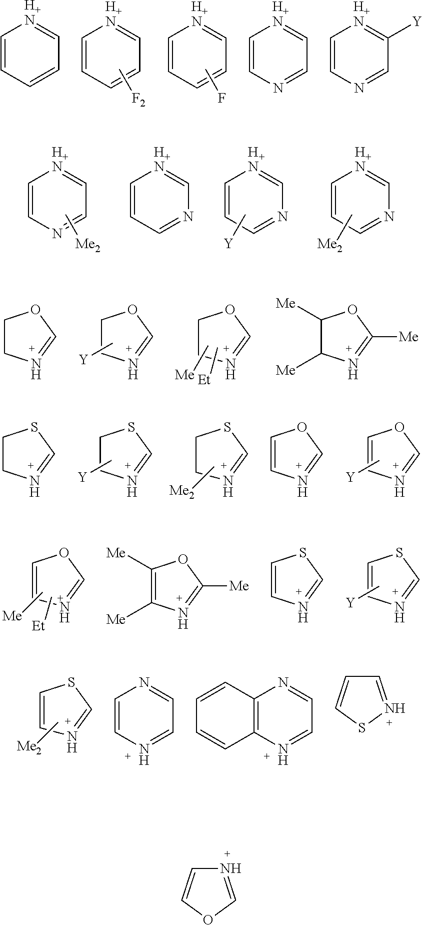

in which Y is alkyl, preferably, methyl or ethyl.

In particular embodiments, the solubility-shifting agent may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; an acid generator such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof.

Alternatively, when the first resist is an NTD resist, the solubility-shifting agent may include a base or base generator. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-butyl 1,3-dihydroxy-2-(hydroxymethyl)propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups cach having 1 to about 8 carbon atoms, and preferably 1 to about 5 carbon atoms such as hydroxymethyl, hydroxyethyl and hydroxybutyl groups. Specific examples of hydroxyamines include mono-, di-and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quarternary ammonium salt, nifedipine, carbamate, and combinations thereof. Exemplary thermal base generators include o-{(.beta.-(dimethylamino)ethyl)aminocarbonyl}benzoic acid, o-{(.gamma.-(dimethylamino)propyl)aminocarbonyl}benzoic acid, 2,5-bis{(.beta.-(dimethylamino)ethyl)aminocarbonyl}terephthalic acid, 2,5-bis{(.gamma.-(dimethylamino)propyl)aminocarbonyl}terephthalic acid, 2,4-bis{(.beta.-(dimethylamino)ethyl)aminocarbonyl}isophthalic acid, 2,4-bis{(.gamma.-(dimethylamino)propyl)aminocarbonyl}isophthalic acid, and combinations thereof.

In one or more embodiments, the solubility-shifting agent includes a solvent. As described above, in some embodiments the solubility-shifting agent is absorbed into the first relief pattern. Accordingly, the solvent may be any suitable solvent that may facilitate absorption into the first relief pattern, provided that it does not dissolve the first photoresist. The solvent is typically chosen from water, organic solvents and mixtures thereof. In some embodiments, the solvent may include an organic-based solvent system comprising one or more organic solvents. The term “organic-based” means that the solvent system includes greater than 50 wt % organic solvent based on total solvents of the solubility-shifting agent composition, more typically greater than 90 wt %, greater than 95 wt %, greater than 99 wt % or 100 wt % organic solvents, based on total solvents of the solubility-shifting agent compositions. The solvent component is typically present in an amount of from 90 to 99 wt % based on the solubility-shifting agent composition.

Suitable organic solvents for the solubility-shifting agent composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C₄-C₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C₅-C₉ fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; and mixtures containing one or more of these solvents.

The solvent included in the absorbed material may depend on the composition and tone of the first resist. When the first resist is formed from a (meth) acrylate polymer, as is typical for ArF resists and the resist is developed as a PTD resist, the solvent system preferably comprises one or more polar organic solvents. For example, a solubility-shifting agent meant to be absorbed into a PTD first photoresist may include a polar solvent such as methyl isobutyl carbinol (MIBC). The solubility-shifting agent may also include aliphatic hydrocarbons, esters, and ethers as cosolvents, such as decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in amount ranging from 1 to 40%, based on the total volume of solvent.

When the first resist is formed from a vinyl aromatic-based polymer, as is typical for KrF and EUV photoresists, and the resist is developed as a PTD resist, the solvent system preferably comprises one or more non-polar organic solvents. The term “non-polar organic-based” means that the solvent system includes greater than 50 wt % of combined non-polar organic solvents based on total solvents of the solubility-shifting agent composition, more typically greater than 70 wt %, greater than 85 wt % or 100 wt %, combined non-polar organic solvents, based on total solvents of the solubility-shifting agent composition. The non-polar organic solvents are typically present in the solvent system in a combined amount of from 70 to 98 wt %, preferably 80 to 95 wt %, more preferably from 85 to 98 wt %, based on the solvent system.

Suitable non-polar solvents include, for example, ethers, hydrocarbons, and combinations thereof, with ethers being preferred. Suitable ether solvents include, for example, alkyl monoethers and aromatic monocthers, particularly preferred of which are those having a total carbon number of from 6 to 16. Suitable alkyl monoethers include, for example, 1,4-cincole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent system further includes one or more alcohol and/or ester solvents. For certain compositions, an alcohol and/or ester solvent may provide enhanced solubility with respect to the solid components of the composition. Suitable alcohol solvents include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C₅₋₉ fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C₄₋₉ monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

When the first resist is formed from a vinyl aromatic-based polymer, a particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

In one or more embodiments, the first resist is a NTD resist, and suitable organic solvents include, but are not limit to, n-butyl acetate, 2-heptanone, propylene glycol methyl ether, propylene glycol methyl ether acetate, and combinations thereof.

In some embodiments, the solubility-shifting agent is coated over the first relief pattern. To properly coat the first relief pattern, the solubility-shifting agent may include a matrix polymer. Any matrix polymer commonly used in the art may be included in the solubility-shifting material. The matrix polymer can be formed from one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbornenes; and combinations thereof. In some embodiments, the polymer contains one or more functional groups chosen, for example, from hydroxy, acid groups such as carboxyl, sulfonic acid and sulfonamide, silanol, fluoroalcohol such as hexafluoroisopropyl alcohol [—C(CF₃)₂OH], anhydrates, lactones, esters, ethers, allylamine, pyrrolidones and combinations thereof. The polymer can be a homopolymer or a copolymer having a plurality of distinct repeat units, for example, two, three, four or more distinct repeat units. In one aspect, the repeat units of the polymer are all formed from (meth)acrylate monomers, are all formed from (vinyl)aromatic monomers or are all formed from (meth)acrylate monomers and (vinyl)aromatic monomers. When the polymer includes more than one type of repeat unit, it typically takes the form of a random copolymer. In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, and combinations thereof.

The solubility-shifting agent compositions typically include a single polymer but can optionally include one or more additional polymers. The content of the polymer in the composition will depend, for example, on the target thickness of the layer, with a higher polymer content being used when thicker layer is desired. The polymer is typically present in the pattern solubility-shifting agent composition in an amount of from 80 to 99.9 wt %, more typically from 90 to 99 wt %, or 95 to 99 wt %, based on total solids of the solubility-shifting agent composition. The weight average molecular weight (Mw) of the polymer is typically less than 400,000, preferably from 3000 to 50,000, more preferably from 3000 to 25,000, as measured by GPC versus polystyrene standards. Typically, the polymer will have a polydispersity index (PDI=Mw/Mn) of 3 or less, preferably 2 or less, as measured by GPC versus polystyrene standards.

Suitable polymers for use in the solubility-shifting agent compositions are commercially available and/or can readily be made by persons skilled in the art. For example, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis (2,4-dimethylvaleronitrile), dimethyl 2,2-azobis(2-methylpropionate), benzoyl peroxide and lauroyl peroxide.

Solubility-shifting agents including a matrix polymer may be coated over the first relief pattern according to methods known in the art. Typically, a solubility-shifting agent that includes a matrix polymer may coated over the first relief pattern by spin coating. The solids content of the solubility-agent may be tailored to provide a film of a desired thickness of the solubility-shifting agent over the first relief pattern. For example, the solids content of the solubility-shifting agent solution can be adjusted to provide a desired film thickness based upon the specific coating equipment utilized, the viscosity of the solution, the speed of the coating tool and the amount of time allowed for spinning. A typical thickness for the composition is from about 200 Å to about 1500 Å.

In one or more embodiments, a solubility-shifting agent includes an active material (i.e., and acid, acid generator, base, or base generator), a solvent, and a matrix polymer as previously described. A typical formulation for such solubility-shifting agent may include about about 1 wt % to about 10 wt % solids and about 90 wt % to 99 wt % solvent, based on the total weight of the solubility shifting agent, where the solids include the active material and the matrix polymer. Within the solids content, the active material may be included in an amount ranging from about about 1 wt % to about 5 wt %.

The solubility-shifting agent may include additives having various purposes, depending on the particular chemistry being used. In some embodiments, a surfactant may be included in the solubility-shifting agent. A surfactant may be included in the solubility-shifting agent to help with coating quality, especially when needing to fill thin gaps between features of the first resist. Any suitable surfactant known in the art may be included in the solubility-shifting agent.

As noted above, in one or more embodiments, the solubility-shifting agent is absorbed into the first relief pattern. Absorption of the solubility-shifting agent into the first relief pattern may be achieved by performing a thermal pretreatment such as a bake. The bake may be a soft bake. The temperature and time of the soft bake may depend on the identity of the first resist, and the desired amount of diffusion of the solubility-shifting agent into the first resist. Typically, a soft bake may be performed for about 30 seconds to about 90 seconds at a temperature ranging from about 50° C. to about 150° C.

After absorption into the first resist, a coating layer that does not include any active solubility-shifting material may remain on the first resist. FIG. 2C shows a substrate including a first relief pattern with absorbed solubility-shifting agent 205 where the coating layer has been removed. In one or more embodiments, the coating layer may be removed by a rinse. The rinse may be accomplished by rinsing the coated substrate with a solvent that dissolves the coating layer but does not dissolve the first resist. The rinse may be carried out using any suitable method, for example, by dipping a substrate in a bath filled with the solvent for a fixed time (dip method), by raising the solvent on a substrate surface by the effect of a surface tension and keeping it still for a fixed time, thereby dissolving the coating layer (puddle method), by spraying the solvent on a substrate surface (spray method), or by continuously ejecting the solvent on a substrate rotating at a constant speed while scanning the solvent ejecting nozzle at a constant rate (dynamic dispense method).

At block 112 of method 100, a second resist is deposited on the substrate. A coated substrate layered with a first relief pattern 204, a solubility-shifting agent 205, and a second resist 206 is shown in FIG. 2D. The second resist may be deposited on the substrate such that it fills gaps of the first relief pattern and is in contact with the first relief pattern or the solubility-shifting agent. In one or more embodiments, the second resist completely covers the substrate, the first relief pattern, and the solubility-shifting agent. The second resist may be deposited on the substrate according to any suitable method known in the art such as, for example, spin-on deposition or vapor-phase treatment.

In one or more embodiments, the second resist includes a polymer. Suitable polymers may be as previously described with respect to the polymer defined as the first resist polymer and/or the matrix polymer. In particular embodiments, suitable polymers may be made from monomers including p-hydroxystryene, styrene, t-butyl acrylate, and combinations thereof. In particular embodiments, the polymer is made from all three of p-hydroxystyrene, styrene, and t-butylacrylate. Such polymer may be prepared from a polymerization reaction including from about 50 to 80% p-hydroxystyrene, from about 10 to 30% styrene, and from about 10 to 30% t-butylacrylate. For example, a polymerization reaction to produce a polymer included in the second resist may include p-hdroxystyrene in an amount ranging from a lower limit of one of about 50%, about 55%, about 60%, and about 65% to an upper limit of one of about 65%, about 70%, about 75%, and about 80%, where any lower limit may be paired with any mathematically compatible upper limit, and styrene and t-butyl acrylate in individual amounts ranging from a lower limit of one of about 10%, about 12%, about 14%, about 16%, about 18%, and about 20% to an upper limit of one of about 20%, about 22%, about 24%, about 26%, about 28%, and about 30%, where any lower limit may be paired with any mathematically compatible upper limit.

The polymer included in the second resist may have a weight average molecular weight (Mw) ranging from about 1 kg/mol to about 100 kg/mol. For example, in one or more embodiments, the second resist may include a polymer having a Mw ranging from a lower limit of one of about 1 kg/mol, about 2 kg/mol, about 5 kg/mol, about 10 kg/mol, about 15 kg/mol, about 20 kg/mol, and about 25 kg/mol to an upper limit of one of about 25 kg/mol, about 50 kg/mol, about 75 kg/mol, about 80 kg/mol, about 90 kg/mol, and about 100 kg/mol, where any lower limit may be paired with any mathematically compatible upper limit. A polymer having such Mw may exhibit desired solubility characteristics, such as, in particular, the dissolution rate.

In one or more embodiments, the second resist includes a solvent. The solvent may be as previously described with respect to the solvent included in the solubility-shifting agent. In particular embodiments, the solvent in the second resist is the same as the solvent in the solubility-shifting agent.

The second resist may include additives having various purposes, depending on the particular chemistry being used. In some embodiments, a quencher is included in the second resist. A quencher may be included in the second resist to help control the diffusion of the active material in the solubility-shifting agent. Suitable quenchers include any of the bases previously listed with reference to the solubility-shifting material.

The second resist may be a PTD or NTD resist. Both PTD and NTD resists may include a polymer and a solvent as described above. In embodiments in which the second resist is an NTD resist, it may also include an acid or acid generator. The acid or acid generator is as previously described with reference to the solubility-shifting material.

At block 114 of method 100 the solubility-shifting agent is diffused into the second resist. In one or more embodiments, diffusion of the solubility-shifting agent into the second resist is achieved by performing a bake. The bake may be carried out with a hotplate or oven. The temperature and time of the bake may depend on the identity of the second resist, and the desired amount of diffusion of the solubility-shifting agent into the second resist. Suitable conditions for the bake may include a temperature ranging from about 50° C. to about 160° C., and a time ranging from about 30 seconds to about 90 seconds. In one or more embodiments, after the bake a solubility-shifted region may be present around the edges of the second resist. The amount of diffusion of the solubility-shifting agent may correspond to the thickness of the solubility-shifted region. In some embodiments, the solubility-shifted region extends into the second resist such that it has a thickness of about 5 to about 60 nm. For example, the thickness of the solubility-shifted region may range from a lower limit of one of about 5 nm, about 10 nm, about 15 nm, about 20 nm, and about 25 nm to an upper limit of one of about 40 nm, about 45 nm, about 50 nm, about 55 nm, and 60 nm, where any lower limit may be paired with any mathematically compatible upper limit. In one or more embodiments, the thickness of the solubility-shifted region may correspond to the desired width of the line that is to be cut into the substrate.

As described previously, the thickness of the solubility-shifted region may correspond to the desired width of the anti-spacers. A coated substrate including a solubility-shifted region is shown in FIG. 2E. As shown in FIG. 2E, the coated substrate includes a substrate layer 202. The substrate is as previously described. The first relief pattern 204, comprised of the first resist 203 and a first fluorescent chemical marker, is on top of the substrate 202. The second resist 206 is coated over the first relief pattern and the substrate. In one or more embodiments, the second resist 206 completely covers the substrate 202 and the first relief pattern 204. A solubility-shifted region 208 of the second resist is shown bordering the first relief pattern.

The solubility-shifted region may have a different solubility than the region of the second resist that was unexposed to the solubility-shifting agent. As such, the solubility-shifted region and the unexposed region of the second resist may be soluble in different resist developers.

At block 116 of method 100, the deposited layer of second resist may be developed using a specific developer such that either the solubility-shifted region or the unexposed region of the second resist remains. In one or more embodiments, the solubility-shifted region of the second resist is developed by first being exposed to actinic radiation, and then being exposed to a specific developer. In other embodiments, the solubility-shifted region of the second resist is only exposed to the specific developer. The specific developer may depend on the tone of the second resist. For example, if the second resist is a positive tone developed resist, the specific developer may be a base such as tetramethylammonium hydroxide. On the other hand, if the second resist is a negative tone developed resist, the specific developer may be a nonpolar organic solvent, such as n-butyl acetate or 2-heptanone.

FIG. 2F shows a coated substrate that has been developed according to embodiments of the present disclosure. In one or more embodiments, the second resist 206 is developed so as to dissolve the solubility-shifted region 208, which is between the first relief pattern and the second resist. Accordingly, dissolution of the solubility-shifted region may result in the formation of trenches 210 between the first relief pattern 204 and the second resist 206 in which the substrate 202 is exposed.

In method 100, referring back to FIG. 1, after developing the second resist, a final fluorescence intensity of the first resist is measured. As described above, the fluorescence intensity may be measured according to methods known in the art. The final fluorescence intensity may be compared against the initial fluorescence intensity to determine critical dimensions of the first resist. In particular, the fluorescence intensity may be used to determine the total volume and the surface absorption of the first resist. For example, the original thickness, the original fluorescence, and the final fluorescence of the first resist may be used to calculate the change in volume. Depending on the feature type (e.g., lines or holes), the average size of the features may also be calculated. A successful or measurable wavelength is dependent on the material absorption and fluorescence.

Method 100 represents one possible embodiment and is not intended to limit the scope of the present invention. As will be appreciated by one of ordinary skill in the art, the present invention may encompass various alternative methods, such as, for example, methods in which the solubility-shifting agent is diffused into the first resist rather than the second resist. Additionally, some methods may include adding the fluorescent chemical to a material other than the first resist such that it is present in any layer of a coated substrate stack, in order to provide information and control over the process. In such alternate embodiments, the components and techniques used in the methods may be as previously described with reference to method 100.

In one or more embodiments, different fluorescent chemical markers may be used in multiple different layers of a coated substrate, depending on the critical dimensions to be determined. For example, in some embodiments, the first resist layer includes a first fluorescent chemical marker, and the second resist layer includes a second fluorescent chemical marker. Accordingly, various critical dimensions may be determined in situ for different layers.

As mentioned above, in one or more embodiments, the solubility-shifting agent is diffused into the first resist. In such embodiments, a method may include initially forming a first relief pattern of a first resist and then coating the first resist with a solubility-shifting agent. At this point, the solubility-shifting agent may be diffused into the first resist a predetermined distance to provide a solubility-shifted region of the first resist. While diffusion of the solubility-shifting agent may occur at a different point in such method and into a different component, diffusion of the solubility-shifting agent may be carried out as descried above in method 100. After the solubility-shifting agent is diffused into the first resist, the second resist may be deposited on the substrate. Then, the substrate may be developed and etched as described with reference to method 100, where the solubility-shifted region of the first resist is soluble in the specific developer.

Any measurement can be sensitized specifically according to the disclosed labelling technique. As the chemicals are removed in the development process, there is no device impact, but metrology is much improved. In methods according to one or more embodiments, a calibration curve on any controlled parameter such as width or diameter may be generated in order to achieve precise measurements. Methods herein may also have a feedforward calibration (to account for height variation).

For example, a series of different inputs on a range of otherwise identical areas may be created. This can be on a single substrate, by taking advantage of site-to-site differences, or on a group of substrates. For optical applications, this can include changing a dose. For thermal applications, this can include changing time and temperature. Then the changes may be measured using a calibrated metrology system (SEM) on the resist as well as an after etch calibration. A look-up table may then be created, or a machine learning/artificial intelligence network may be created and used, or a calibration linearity may be created (for example, 1 nm of diameter per second of time). The generation of calibration curves for such purpose is conventional in the art, though applied herein on unconventional materials.

In one embodiment, techniques include measuring a weight change. The weight change may be measured on the substrate level only. An incoming substrate may be measured to identify an initial weight. Then, processing may be executed, including coating with a solubility-shifting agent, layering with a second resist, diffusing the solubility-shifting agent, and developing the second resist. After processing, the wafer may be measured again to identify a modified weight and/or a difference in weight.

In one or more embodiments, processing of optical methods includes measuring a change in diameter/width by using calibrations from the measurement system in question and calculating a correction curve for each target arca. Optionally, a smoothed calculation can be created, and any input from feedforward can be used. It will be understood that feedforward indicates incorporating measurements to modify the process if the measurement deviates from a predetermined value. Data measured and calculated according to methods described herein can be used to correct a hot plate, to change the mean temperature or to correct an optical tool, which corrects for variance using optical dose. Thus, dye-based measurements described herein, such method 100 in FIG. 1, may be used to optimize scanners and track tools.

In one or more embodiments, one or more layers of interest are deposited. The layers contain one or more dyes or chemical markers. Suitable layers may be polymer layers, organic layers, or resist layers. The layers may be measured prior to treatment for weight and/or volume measurement by unit area. One or more treatment processes may then be executed. Then, the wafer and/or regions of the wafer are measured (post treatment). Spectra from pre-treatment measurement and post-treatment measurement can then be compared to find differences and calculate values. Changes in volume can be converted, given known height and amount, to changes in diameter.

Based on measured values, parameters for a subsequent substrate can be adjusted based on current data. This may be an adjustment to the unique thermal or optical activation. In one or more embodiments, to increase the width of a removed region, the temperature/time may be adjusted to increase the amount of diffusion into the second resist. For example, after calibration, if the known tradeoff is 1 sec/nm diffusion, and if the measured amount of diffusion was off by 0.23 nm, then the process diffusion time would change by 0.23 sec. In an optical tuning case, where, for example, there are optically activated portions of the resist, there will be a calibration of dose vs. size. If, for example, that is 1 mJ/cc per nanometer, then a 0.23 nm shift will need 1 mJ of dose to adjust and may be updated accordingly.

Methods of one or more embodiments include measuring the fluorescence intensity only once to determine a critical dimension of a resist layer such as, for example, volume. Such methods include depositing a first layer of a first photoresist that includes a first chemical marker on a substrate, forming a first relief pattern from the first layer that defines openings, and depositing a second photoresist on the substrate, the second photoresist filling openings defined by the first relief pattern. Then, the method includes diffusing a solubility-shifting agent a predetermined distance into the second photoresist creating a diffusion region, the solubility-shifting agent selected to cause the second photoresist to become soluble to a specific developer, removing the diffusion region from the substrate thereby defining openings between the second photoresist and the first photoresist, and measuring a fluorescence intensity of the first layer from the first chemical marker subsequent to removing the diffusion region.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

1. A method of microfabrication, the method comprising:
depositing a first layer of a first resist on a substrate, wherein the first resist comprises a first fluorescent chemical marker;
measuring a first fluorescence intensity of the first layer from the first fluorescent chemical marker;
after measuring a first fluorescence intensity of the first layer, forming a first relief pattern from the first layer of the first resist;
after forming the first relief pattern from the first layer of the first resist, measuring a second fluorescence intensity of the first layer from the first fluorescent chemical marker;
depositing a solubility-shifting agent on the first relief pattern;
depositing a second resist on the first relief pattern;
diffusing the solubility-shifting agent a predetermined distance into the second resist to provide a solubility-shifted region of the second resist, wherein the solubility-shifting region of the second resist borders the first relief pattern;
developing the second resist such that the solubility-shifted region of the second resist is dissolved, providing openings between the first relief pattern and the second resist where a portion of the substrate is exposed; and
measuring a third fluorescence intensity of the first layer from the first fluorescent chemical marker subsequent to developing the second resist.

2. A method of microfabrication, the method comprising:
depositing a first layer of a first resist on a substrate, wherein the first resist comprises a first fluorescent chemical marker;
measuring a first fluorescence intensity of the first layer from the first fluorescent chemical marker;
after measuring the first fluorescence intensity of the first layer, forming a first relief pattern from the first layer of the first resist;
after forming the first relief pattern from the first layer of the first resist, measuring a second fluorescence intensity of the first layer from the first fluorescent chemical marker;
depositing a solubility-shifting agent on the first relief pattern;
diffusing the solubility-shifting agent a predetermined distance into the first resist to provide a solubility-shifted region of the first resist;
depositing a second resist on the first relief pattern;
developing the first resist such that the solubility-shifted region of the first resist is dissolved, providing openings between the first relief pattern and the second resist where a portion of the substrate is exposed; and
measuring a third fluorescence intensity of the first layer from the first fluorescent chemical marker subsequent to developing the first resist.

3. The method of claim 1, further comprising:
adding a second fluorescent chemical marker to the second resist;
prior to developing the second resist, measuring a fluorescence intensity of the second resist from the second fluorescent chemical marker; and
after developing the second resist, measuring a fluorescence intensity of the second resist from the second fluorescent chemical marker.

4. The method of claim 1, wherein an absolute fluorescence intensity is measured for a predetermined wavelength.

5. The method of claim 1, wherein the first fluorescent chemical marker is a dye.

6. The method of claim 5, wherein the dye is selected from the group consisting of BODIPY dyes, cyanine 3 dyes, cyanine 5 dyes, cyanine 5.5 dyes, cyanine 7 dyes, fluorescein dyes, rhodamine dye, Coumarin dyes, 800CW dye, BP Fluor 680, BP Fluor 647, BP Fluor 594, BP Fluor 568, BP Fluor 546, BP Fluor 555, BP Fluor 350, BP Fluor 488, BP Fluor 430, BP Fluor 532, 4-(9H-carbazol-9-yl)benzoate, and 4-(dicyanomethylene)-2-methyl-6-(4-dimethylaminostyryl)4H-pyran.

7. The method of claim 1, further comprising:
calculating a critical dimension of the solubility-shifted region;
identifying a critical dimension of the solubility-shifted region outside a predetermined value range; and
alerting a corresponding semiconductor manufacturing tool for process adjustment.

8. The method of claim 1, further comprising:
calculating a volume measurement of the first resist;
identifying a volume measurement of the solubility-shifted region outside a predetermined value range; and
adjusting a corresponding semiconductor manufacturing tool to provide a subsequent volume measurement closer to the predetermined value range.

9. The method of claim 1, further comprising:
calculating a volume measurement of the second resist;
identifying a volume measurement outside a predetermined value range; and
adjusting a corresponding semiconductor manufacturing tool to provide a subsequent volume measurement on a subsequent wafer that is closer to or within the predetermined value range.

10. The method of claim 1, wherein forming the first relief pattern includes forming a calibration design relief pattern for calibration of critical dimensions.

11. The method of claim 10, wherein a critical dimension is volume.

12. The method of claim 1, wherein the solubility-shifting agent comprises an acid generator.

13. The method of claim 12, wherein the acid generator is free of fluorine.

14. The method of claim 12, wherein the acid generator is selected from the group consisting of pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, triphenylsulfonium antiomate, and combinations thereof.

15. The method of claim 1, wherein the solubility-shifting agent comprises an acid.

16. The method of claim 15, wherein the acid is free of fluorine.

17. The method of claim 15, wherein the acid is selected from the group consisting of trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, and combinations thereof.

18. The method of claim 1, wherein the solubility-shifting agent comprises a matrix polymer comprising monomers with ethylenically unsaturated polymerizable double bonds, including (meth)acrylate monomers; (meth)acrylic acids; styrene; hydroxystyrene; vinyl naphthalene; acenaphthylene; vinyl alcohol; vinyl chloride; vinyl pyrrolidone; vinyl pyridine; vinyl amine; vinyl acetal; maleic anhydride;
maleimides; norbornenes; and combinations thereof.

19. The method of claim 1, wherein the solubility-shifting agent comprises a matrix polymer comprising monomers comprising one or more functional groups chosen from hydroxy, carboxyl, sulfonic acid, sulfonamide, silanol, fluoroalcohol, anhydrates, lactones, esters, ethers, allylamine, pyrrolidones, and combinations thereof.

20. The method of claim 1, wherein the solubility-shifting agent comprises a solvent selected from the group consisting of methyl isobutyl carbinol (MIBC), decane, isoobutyl isobutyrate, isoamyl ether, and combinations thereof.

21. (canceled)

22. (canceled)
